(19) United States
(12) Patent Application Publication
(10) Pub. No.: US 2005/0009274 A1
(43) Pub. Date: Jan. 13, 2005

(54) Method of manufacturing flash memory device

(76) Inventor: Cha Deok Dong, Kyungki-Do (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/738,270

(22) Filed: Dec. 17, 2003

(30) Foreign Application Priority Data
Jul. 11, 2003 (KR) 2003-47107

(51) Int. Cl. H01L 21/336

(52) U.S. Cl. 438/257

(57) ABSTRACT

Provided is a method of manufacturing a flash memory device, comprising the steps of; forming an undoped first poly silicon film on a semiconductor substrate; forming an undoped second poly silicon film having a high concentration doping area on the first poly silicon film; and forming a dielectric film on the resultant structure, so that doping concentrations of the first poly silicon film and the second poly silicon film come to be similar. Accordingly, the first poly silicon film and the second poly silicon film constituting the floating gate electrode have the same doping concentration, and therefore, it is possible to form the dielectric film having an effective thickness by minimizing a growth of a native oxide film on the resultant structure at the time of forming the dielectric film.

### BACKGROUND

1. Field of the Invention

The present invention relates to a method of manufacturing a flash memory device.

2. Discussion of Related Art

Generally, a floating gate electrode is formed by sequentially laminating an undoped first poly silicon film (i.e. a poly silicon film adjacent to a tunnel oxide film) and a doped second ploy silicon film (i.e. a poly silicon film adjacent to a dielectric substrate film) and patterning them. At that time, a doping concentration of the doped second poly silicon film is higher than that of a bulk doping concentration of the floating gate electrode (i.e. whole doping concentration of the floating gate electrode). Therefore, ions between the poly silicon films having different doping concentrations are diffused during a following high heat treatment process such as an oxidation process.

As a result, when a dielectric film is formed on the first and the second poly silicon films having non-uniform concentrations, a doping concentration on the second poly silicon film is high. Therefore, there is a problem that although the dielectric film is deposited with controlling a thickness thereof, it is very difficult to form the dielectric film having an effective thickness to be desired since a native oxide film or the like are formed.

Furthermore, in order to solve the problem, when decreasing the bulk concentration of the floating gate electrode, another problem is generated, that is, ions doped on the first poly silicon film do not diffuse to form a depletion layer.

### SUMMARY OF THE INVENTION

Therefore, the present invention is contrived to solve the aforementioned problems in the art, and is directed to a method of manufacturing a flash memory device capable of forming a dielectric film having an effective thickness on a floating gate electrode.

One aspect of the present invention is to provide a method of manufacturing a flash memory device, comprising the steps of; forming an undoped first poly silicon film on a semiconductor substrate; forming an undoped second poly silicon film having a high concentration doping area on the first poly silicon film; and forming a dielectric film on the resultant structure, so that doping concentrations of the first poly silicon film and the second poly silicon film come to be similar.

In the aforementioned the method of manufacturing the flash memory device according to another embodiment of the present invention, the second poly silicon film is formed at a temperature of about 480° C. to about 550° C. under a pressure of about 0.1 torr to about 3 torr by a LP-CVD method using Si source gas such as SiH₄ or SiH₆ and PH₃ gas, and then the high concentration doping area is formed adjacent to the first poly silicon film by flowing the SiH₄ gas of about 500 to about 1500 sccm and the PH₃ gas of about 100 to about 200 sccm into the second poly silicon film. In addition, the high concentration doping area is formed by using only a SiH₄ gas. At that time, it is preferable that ratio of the high concentration doping area to the undoped area is 1:3.

In the aforementioned the method of manufacturing the flash memory device according to another embodiment of the present invention, the high concentration doping area is preferably formed to have a doping concentration of about 3E20 to about 5E20 atoms/cc.

In the aforementioned the method of manufacturing the flash memory device according to another embodiment of the present invention, the dielectric film is formed to have an ONO structure in which a first oxide film, a nitride film, and a second oxide film are sequentially laminated, and the first oxide film and the second oxide film are formed at a temperature in the range of about 810° C. to about 850° C. and the nitride film is formed at a temperature in the range of about 650° C. to about 800° C.

In the aforementioned the method of manufacturing the flash memory device according to another embodiment of the present invention, a step of forming a floating gate electrode and a control gate electrode by carrying out a photograph etching process to a predetermined area of the resultant structure, after a third poly silicon film for the control gate electrode and a metal silicide film are formed on the dielectric film, is further comprised.

### BRIEF DESCRIPTION OF THE DRAWINGS

The above and other objects, advantages and features of the present invention will become apparent from the following description of preferred embodiments given in conjunction with accompanying drawings, in which:

FIGS. 1 and 2 are cross-sectional views illustrating a method of manufacturing a flash memory device according a preferable embodiment of the present invention.

FIG. 3 is a graph showing a doping profile of a floating gate electrode according to the present invention.

### DETAILED DESCRIPTION OF PREFERRED EMBODIMENTS

Now, preferable embodiments of the present invention will be described with reference to accompanying drawings. However, the present invention is not limited to the preferred embodiments disclosed in the following description, but can be implemented into various changes and modifications. Thus, these embodiments according to the invention are for informing those skilled in the art of the scope of the present invention.

Therefore, a thickness of film in the drawing is represented for convenience of explanation and the same component in the drawings is referred to the same numerals. Furthermore, in this description, terms “any film is provided or contacted on or to another film or a semiconductor substrate” means that any film may be directly provided or contacted on or to the to another film or a semiconductor substrate, or any film may be provided or contracted on or to the other film or a semiconductor substrate via still another films.

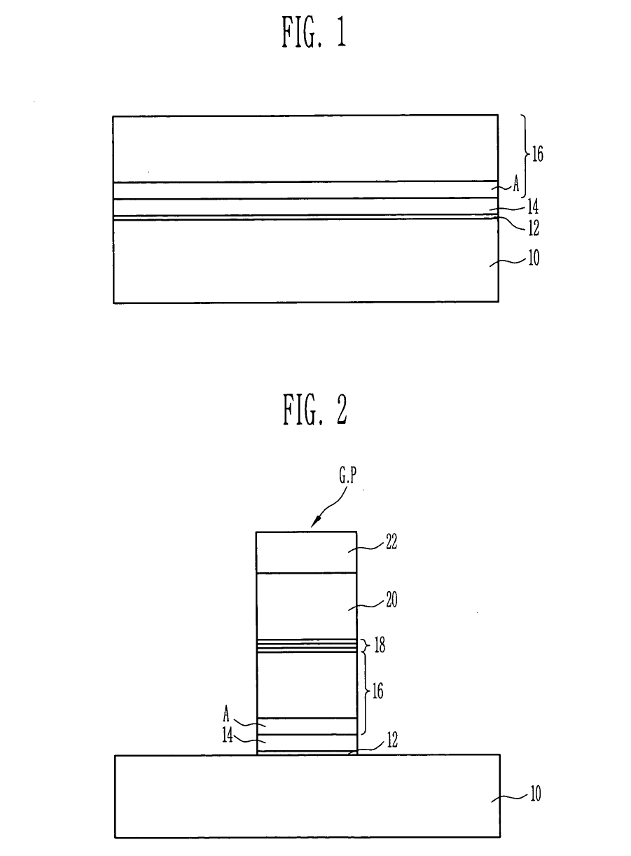

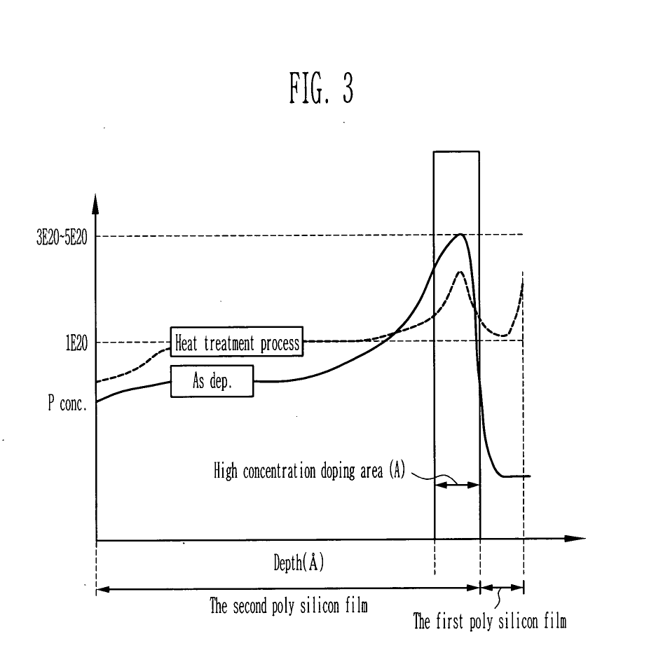

FIGS. 1 and 2 are cross-sectional views illustrating a method of manufacturing a flash memory device according to the present invention and FIG. 3 is a graph showing a doping profile of a floating gate according to the present invention.

Referring to FIG. 1, a tunnel oxide film 12 and a first poly silicon film 14 for floating gate electrode are sequentially formed on a semiconductor substrate 10.

At that time, in the semiconductor substrate 10, a PMOS area and an NMOS area are separately defined and a well area (not shown) and a threshold voltage controlling ion implantation area (not shown) of the PMOS area, a well area (not shown) and a threshold voltage controlling ion implantation area (not shown) of the NMOS area are formed respectively.

The tunnel oxide film 12 can be formed by carrying out a wet-oxidizing process at a temperature range of about 750 to about 800° C. and carrying out a heat treatment at a temperature range of about 900 to about 910° C. under a N₂ gas atmosphere for 20 to 30 minute.

The first poly silicon film 14 for the floating gate electrode, which is an undoped poly silicon film, can be formed by a low pressure chemical vapor deposition (herein after referred to as “LP-CVD”) using Si source gas such as SiH₄ or SiH₆ at a temperature range of about 480 to about 550° C. under a pressure range of about 0.1 torr to about 3 torr.

A pad nitride film (not shown) is formed on the first poly silicon film 14 and then a photoresist pattern (not shown) is formed. Next, using the pattern as an etching mask, the first poly silicon film 14, the tunnel oxide film 12, and the semiconductor substrate 10 are etched to form a trench (not shown) for defining an element isolation area. The element isolation film (not shown) is formed by carrying out a planarization process such as a chemical mechanical polishing (CMP) until the pad nitride film (not shown) is exposed after a high density plasma (HDP) oxide film excellent in a gap fill characteristic is deposited to fill the trench (not shown). The pad nitride film (not shown) is removed using an etching process.

Next, a second poly silicon film 16, a dielectric film 18, a third poly silicon film 20 for a control gate electrode, and a metal silicide film 22 are sequentially formed on the resultant structure.

The second ploy silicon film 16 for the floating gate electrode is formed to have a high concentration doping area A at an area adjacent to the first poly silicon film 14. When a subsequent heat treatment process is carried out, ions doped in the second poly silicon film 16 are diffused, and therefore a total doping concentration of the first poly silicon film 14 and the second poly silicon film 16 becomes about 1E20 atoms/cc. As a result, a doping concentration of the first poly silicon film 14 is equal to that of the second poly silicon film 16. Therefore, the poly silicon films have a uniform doping concentration and the doping concentration on the second poly silicon film 16 is decreased, whereby it is possible to form the dielectric film having an effective thickness by minimizing growth of the native oxide film at the time of forming a dielectric film having an ONO structure.

The second poly silicon film is formed at a temperature of about 480 to about 550° C. under a pressure of about 0.1 torr to about 3 torr by a LP-CVD method using Si source gas such as SiH₄ or SiH₆ and PH₃ gas, and then the high concentration doping area having a doping concentration of about 3E20 to about 5E20 atoms/cc is formed adjacent to the first poly silicon film, by flowing the SiH₄ gas of about 500 to about 1500 sccm and the PH₃ gas of about 100 to about 200 sccm into the second poly silicon film.

In addition, the high concentration doping area could be formed by using only a SiH₄ gas.

It is preferable that the dielectric film 18 is constructed to sequentially laminate a first oxide film, a nitride film, and a second oxide film. At that time, the first oxide film and the second oxide film can be formed to have a thickness of about 35 to about 60 Å using the LP-CVD method at a temperature in the range of about 600 to 850° C. under a pressure in the range of about 1 torr to about 3 torr as any one of a high temperature oxide (HTO) film using SiH₂Cl₂ (DichloroSilane; DCS) as a source gas or an HTO film using N₂O gas as a source gas. The nitride film can be formed to have a thickness of about 50 to about 65 Å by the LP-CVD method at a temperature range of about 650 to about 800° C. under a pressure range of 1 torr to 3 torr using NH₃ and SiH₂Cl₂ gas as reaction gas.

At the time of forming such a dielectric film, ions doped in the second poly silicon film having a high concentration doping area are diffused into the first poly silicon film, whereby the concentration of the floating gate electrode becomes uniform and the doping concentration on the second poly silicon film is decreased. Accordingly, it is possible to form the dielectric film with minimizing a growth of the native oxide film on the second poly silicon film.

The third poly silicon film 20 for the control gate electrode is formed to have a thickness of about 700 to about 1500 Å at a temperature of about 500 to about 550° C. under a pressure of about 0.1 torr to about 3 torr by a LP-CVD method using Si source gas such as SiH₄ or SiH₆ and PH₃ gas, at that time, the third poly silicon film can be formed as a poly silicon film having a doping concentration which is equal to the doping concentration of the second poly silicon film 16 for the floating gate electrode, that is, about 1.0 to about 1.7E20 atoms/cc.

The metal silicide film 22 is formed as a tungsten silicide film to have a thickness of about 1000 to about 1200 Å by reacting SiH₄ (monosilane: MS) or SiH₂Cl₂ (DichloroSilane: DCS) and WF₆ and is controlled to minimize sheet resistances of the films into a stoichiometric ratio of 2.0 to 2.8.

Referring to FIG. 2, the photoresist pattern (not shown) is formed on the resultant structure, and is etched to form a gate electrode pattern G.P using an etching mask. Subsequently, a source and drain area (not shown) is formed by carrying out an ion implantation process using the gate electrode pattern G.P as an ion implantation mask, and then the flash memory device is completed.

FIG. 3 is a graph comparing a doping profile of a floating gate electrode having the second poly silicon film according to the present invention and a doping profile of the floating gate electrode having the second poly silicon film after a high heat treatment process such as the oxidizing process is carried out.

In the present invention, the first poly silicon film and the second poly silicon film constituting the floating gate electrode have the same doping concentration, and therefore, the dielectric film having an effective thickness is formed by minimizing a growth of a native oxide film on the resultant structure at the time of forming the dielectric film.

As described above, according to the present invention, the first poly silicon film and the second poly silicon film constituting the floating gate electrode have the same doping concentration, and therefore, it is possible to form the dielectric film having an effective thickness by minimizing a growth of a native oxide film on the resultant structure at the time of forming the dielectric film.

The specific embodiments of the present invention were described in detail in the aforementioned description. However, it is apparent that the present invention can be implemented into various changes and modifications by those who skilled in the art without departing from the scope of the present invention.

1. A method of manufacturing a flash memory device, comprising steps of;
forming an undoped first poly silicon film on a semiconductor substrate;
forming an undoped second poly silicon film having a high concentration doping area on the first poly silicon film; and
forming a dielectric film on the resultant structure, so that doping concentrations of the first poly silicon film and the second poly silicon film come to be similar.

2. The method of claim 1, wherein the second poly silicon film is formed at a temperature of about 480° C. to about 550° C. under a pressure of about 0.1 torr to about 3 torr by a LP-CVD method using Si source gas such as SiH₄ or SiH₆ and PH₃ gas, and then the high concentration doping area is formed adjacent to the first poly silicon film by flowing the SiH₄ gas of about 500 to about 1500 sccm and the PH₃ gas of about 100 to about 200 sccm into the second poly silicon film.

3. The method of claims 2, wherein the high concentration doping area is formed to have a doping concentration in the range of about 3E30 atoms/cc to about 5E20 atoms/cc.

4. The method of claim 1, wherein the high concentration doping area is formed by using only a SiH₄ gas.

5. The method of claims 4, wherein the high concentration doping area is formed to have a doping concentration in the range of about 3E30 atoms/cc to about 5E20 atoms/cc.

6. The method of claims 1, wherein the high concentration doping area is formed to have a doping concentration in the range of about 3E30 atoms/cc to about 5E20 atoms/cc.

7. The method of claim 1, wherein the dielectric film is formed to have an ONO structure in which a first oxide film, a nitride film, and a second oxide film are sequentially laminated, and the first oxide film and the second oxide film are formed at a temperature in the range of about 810° C. to about 850° C. and the nitride film is formed at a temperature in the range of about 650° C. to about 800° C.

8. The method of claim 1, further comprising a step of forming a floating gate electrode and a control gate electrode by carrying out a photograph etching process to a predetermined area of the resultant structure after a third poly silicon film for the control gate electrode and a metal silicide film are formed on the dielectric film.
